(19) United States
(12) Patent Application Publication
(10) Pub. No.: US 2009/0127541 A1
(43) Pub. Date: May 21, 2009

(54) REDUCING DEFECTS IN SEMICONDUCTOR QUANTUM WELL HETEROSTRUCTURES

(75) Inventors: Prashant Majhi, Austin, TX (US); Wilman Tsai, Saratoga, CA (US); Jack T. Kavalieros, Portland, OR (US)

Correspondence Address: COOL PATENT, P.C.;c/o CPA Global, P.O. BOX 52050, MINNEAPOLIS, MN, 55402, US

(73) Assignee: INTEL CORPORATION, Santa Clara, CA (US)

(21) Appl. No.: 11/942,312

(22) Filed: Nov. 19, 2007

(51) Int. Cl. H01L 21/205; H01L 29/12

(52) U.S. Cl. 257/14; 438/503; 257/E29.069; 257/E21.104

(57) ABSTRACT

Reducing defects in semiconductor quantum well structures is generally described. In one example, an apparatus includes a semiconductor substrate including silicon, a buffer film epitaxially grown on the semiconductor substrate, the buffer film comprising silicon, germanium, and an impurity, and a first semiconductor film epitaxially grown on the buffer film wherein a lattice mismatch exists between the semiconductor substrate and the first semiconductor film and wherein the impurity disrupts lattice structure dislocation gliding in at least the first semiconductor film.

### BACKGROUND

High mobility channel materials such as strained heterostructures including silicon (Si) and germanium (Ge) are being explored to replace pure silicon in semiconductor devices.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1a-1c depict the formation of a quantum well heterostructure, according to but one embodiment;

FIG. 2 is a flow diagram of a method to reduce defects in a quantum well heterostructure, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of reducing defects in semiconductor quantum well heterostructures are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

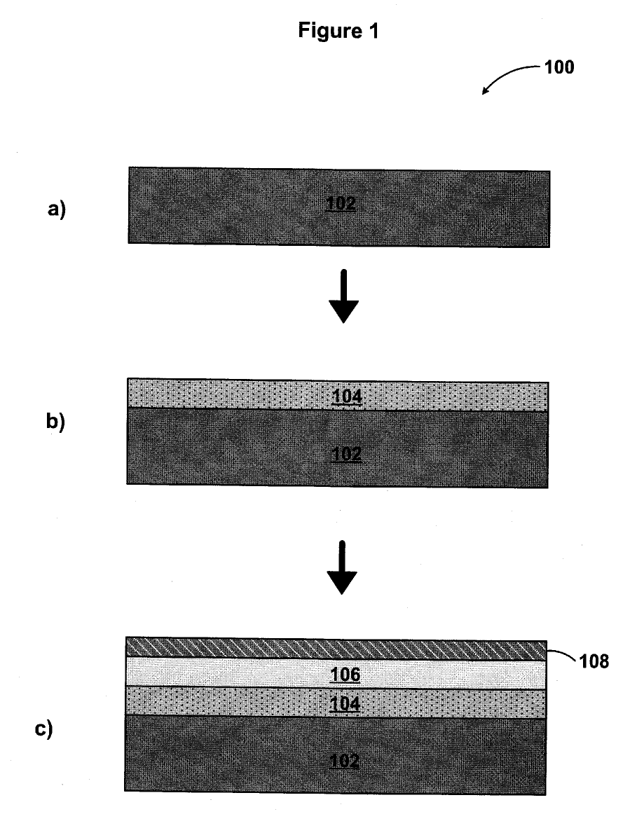

FIGS. 1a-1c depict the formation of a quantum well heterostructure 100, according to but one embodiment. In an embodiment according to FIG. 1a, an apparatus 100 includes a semiconductor substrate 102. In an embodiment according to FIG. 1b, an apparatus 100 includes a buffer film 104 coupled with the semiconductor substrate 102. In an embodiment according to FIG. 1c, an apparatus 100 includes a first semiconductor film 106 coupled with the buffer film 104, and a second semiconductor film 108 coupled with the first semiconductor film 106, each coupled as shown. In an embodiment, a semiconductor substrate 102 includes silicon.

High mobility channel materials such as strained heterostructures including silicon (Si) and germanium (Ge) are being explored to replace pure silicon in semiconductor devices. However, a lattice mismatch between different materials such as between a semiconductor substrate 102 and a first semiconductor film 106 may cause dislocation defect pile-up and growth during hetero-epitaxy of lattice-mismatched materials. For example, when pure Ge 106 (without impurity) is epitaxially deposited on Si 102, dislocation networks are formed to relax built-up strain between the lattice-mismatched Ge and Si. The dislocation networks then interact to form threading dislocations that go through the films. Such defects may prevent the reliable integration of strained Si/Ge/Si and/or SiGe/Ge/SiGe/Si heterostructures into Si-based complementary metal-oxide-semiconductor field-effect transistor (CMOSFET) platforms, for example. Embodiments disclosed herein may significantly reduce such dislocation defects in quantum well heterostructures 100 and/or enable the formation of high performance MOSFETs on Ge-based quantum wells 106, 108. Benefits of such an apparatus 100 include the ability to form substantially defect-free channel material 106, 108 where the percentage of germanium and strain level in the channel material may be designed or engineered according to desired results. Embodiments for apparatus 100 may also enable well-controlled growth of quantum wells to populate the sub-band with lower effective mass.

Strain engineering of channel materials 106, 108 may be enabled by a thin buffer 104 film 104 having an impurity wherein the buffer film 104 is substantially free from dislocation defects. The buffer film 104 may be thinner than buffer films without an impurity. A buffer film 104 may be epitaxially grown on the silicon substrate 102. In an embodiment, the buffer film 104 includes germanium and an impurity. In another embodiment, the buffer film includes silicon, germanium, and an impurity to reduce dislocation defects and/or provide stress relaxation between the substrate 102 and films 106 and/or 108. For example, the impurity may be any impurity that provides stress relaxation between lattice-mismatched films or reduces dislocation defects in a quantum well heterostructure 106, 108 that is formed upon the semiconductor substrate 102 and/or buffer film 104.

In an embodiment, the impurity is a group IV isovalent of the periodic table that disrupts lattice structure dislocation gliding in the buffer film 104 and/or first 106 and/or second 108 semiconductor films. In an embodiment, the impurity of the buffer film 104 is carbon. In another embodiment, the buffer film includes less than about 5% carbon by atomic percentage. In yet another embodiment, a precursor gas used to deposit the buffer film 104 is combined with an impurity to deposit the impurity to the interface between substrate 102 and quantum well heterostructures 106, 108. In an embodiment wherein the buffer film 104 includes silicon, germanium, and carbon, the ratio of silicon to germanium in the buffer film 104 is about one atom of germanium for every atom of silicon. In an embodiment, a buffer film 104 includes about 30% to 70% germanium. In another embodiment, a buffer film 104 includes greater than or equal to about 50% germanium and less than a bout 5% carbon wherein the percentages in this description are atomic percentages. In an embodiment, the buffer film 104 is about 10 to 50 nm thick.

A buffer film 104 may be selectively grown on active regions of the semiconductor substrate 102. For example, a buffer film 104 may be selectively deposited only to the PMOS active region of a high performance logic area, according to one embodiment. Selective deposition of a buffer film 104 may be accomplished using hard mask patterning or any other suitable method for selective deposition.

In another embodiment, a buffer film 104 is replaced with an implant of the impurity to the surface of substrate 102 such that the impurity is introduced to the interface between the substrate 102 and a first semiconductor film 104. Such implant may occur before deposition of film 106, for example. In an embodiment, carbon is implanted into the surface of a silicon substrate 102 to prevent dislocation defects in pure germanium 106 epitaxially deposited directly to the silicon substrate 102.

In an embodiment, a first semiconductor film 106 is epitaxially deposited or grown on the buffer film 104. The first semiconductor film 106 includes strained germanium wherein a lattice mismatch exists between the semiconductor substrate 102 and the first semiconductor film 106, according to an embodiment. In another embodiment, the first semiconductor film 106 includes compressively strained germanium and the lattice mismatch between the semiconductor substrate 102 and the first semiconductor film 106 is about 4%.

In an embodiment, a second semiconductor film 108 is epitaxially grown or deposited to the first semiconductor film 106. The second semiconductor film 108 includes tensile-strained silicon according to an embodiment. In another embodiment, the second semiconductor film 108 includes tensile-strained silicon-germanium. In an embodiment, the use of carbon at the interface between a silicon substrate 102 and films 104, 106, or 108 formed thereon enables the formation of substantially defect-free SiGe (i.e. −50% Ge) 104 directly on Si 102. A compressively strained Ge film 106 may be epitaxially deposited to the SiGe buffer film 104 and a tensile-strained Si film 108 may be epitaxially deposited to the Ge film 106 to form a strained quantum well structure 106, 108. In an embodiment, the first semiconductor film 106 and the second semiconductor film 108 form a quantum well heterostructure for use as a channel material in a CMOS device.

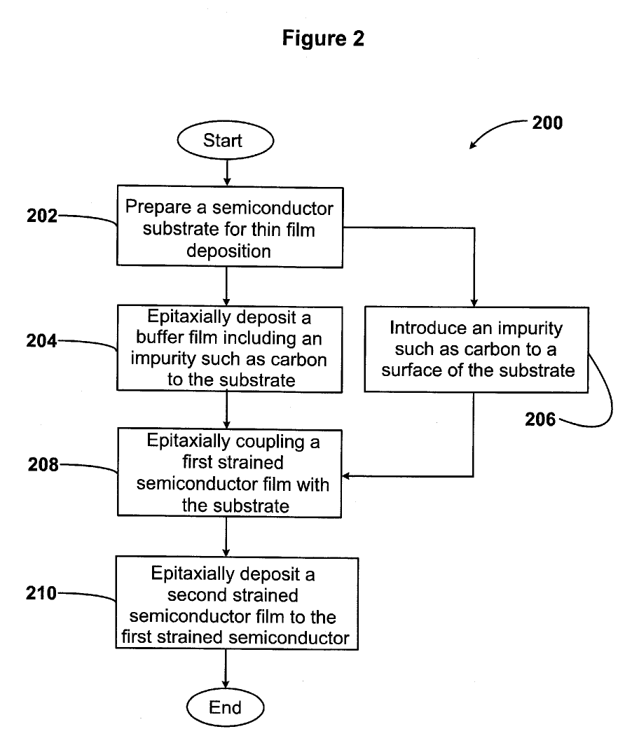

FIG. 2 is a flow diagram of a method to reduce defects in a quantum well heterostructure 200, according to but one embodiment. In an embodiment, a method 200 includes preparing a semiconductor substrate for thin film deposition 202, epitaxially depositing a buffer film including an impurity such as carbon to the substrate 204 or introducing an impurity such as carbon to a surface of the substrate 206, epitaxially coupling a first strained semiconductor film with the substrate 208, and epitaxially depositing a second strained semiconductor film to the first strained semiconductor film 210, with arrows providing a suggested flow. Embodiments already described for FIGS. 1a-1c may be incorporated in method 200, according to an embodiment.

In an embodiment, preparing a semiconductor substrate for thin film deposition 202 at least includes providing a clean substrate surface. In an embodiment, a method 200 includes introducing an impurity 206 to the surface of a substrate including silicon, and epitaxially coupling a first semiconductor film with the substrate 208, the first semiconductor film including strained germanium wherein a lattice mismatch exists between the substrate and the first semiconductor film. In an embodiment, the impurity provides stress relaxation or reduces dislocation defects in a quantum well heterostructure formed on the substrate. In an embodiment, epitaxially coupling a first semiconductor film with a substrate 208 allows for an impurity to be introduced to the surface of the substrate 206 by implantation or by epitaxially depositing a buffer film including an impurity such as carbon to the substrate 204 and subsequently epitaxially depositing a first strained semiconductor film to the buffer film 208. In other words, epitaxially coupling a first strained semiconductor film with the substrate 208 includes epitaxially depositing a first strained semiconductor film to a buffer film, wherein the buffer film is epitaxially coupled to the substrate.

In an embodiment, introducing an impurity to a surface of the substrate 206 includes epitaxially depositing a buffer film including at least germanium and an impurity to the substrate 204 using atomic layer deposition (ALD), physical vapor deposition (PVD), chemical vapor deposition (CVD), or suitable combinations thereof. The buffer film is disposed between the substrate and the first semiconductor film according to an embodiment. In an embodiment, introducing an impurity 206 includes selectively introducing an impurity to active regions of a semiconductor substrate. In another embodiment, the impurity is a group IV isovalent that disrupts lattice structure dislocation gliding in at least the first semiconductor film.

Introducing an impurity 206 includes implanting a surface of the substrate with an impurity such as carbon, for example, according to an embodiment. In an embodiment of introducing an impurity to substrate surface by implantation 206, depositing a buffer film 204 may not be necessary.

In an embodiment, a buffer film includes about 30% to 70% germanium. In an embodiment, a buffer film includes greater than or equal to about 50% germanium and less than about 5% carbon, where the percentages are atomic percentages. In another embodiment, a buffer film includes germanium, silicon, and an impurity wherein the atomic ratio of silicon to germanium in the buffer film is about one atom of germanium for every atom of silicon. In another embodiment, the buffer film is about 10 to 50 nm thick.

In an embodiment, a method 200 includes epitaxially depositing a second semiconductor film to the first semiconductor film 210, the second semiconductor film including strained silicon wherein the first and second semiconductor film form a quantum well heterostructure for use as a channel material in a complementary metal-oxide-semiconductor (CMOS) device. In an embodiment, a first semiconductor film includes compressively strained germanium and a second semiconductor film includes tensile-strained silicon.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

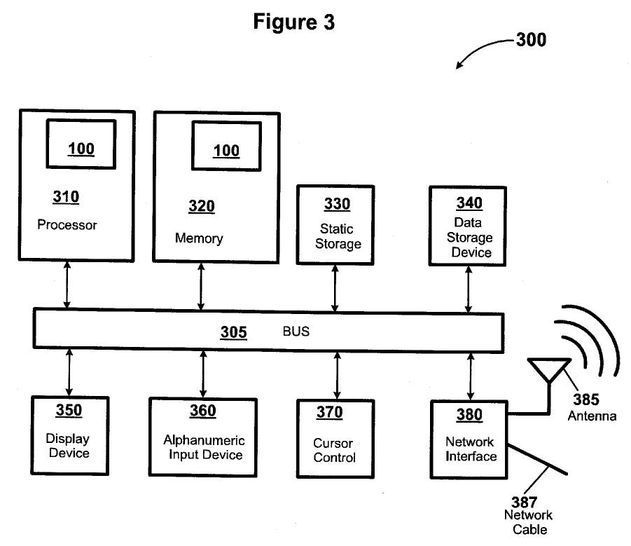

FIG. 3 is a diagram of an example system in which embodiments of the present invention may be used 300, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes an apparatus having heterostructures 100 in accordance with embodiments described with respect to FIGS. 1-2. In an embodiment, an apparatus having heterostructures 100 as described herein is part of an electronic system's processor 310 or memory 320.

Electronic system 300 may include bus 305 or other communication device to communicate information, and processor 310 coupled to bus 305 that may process information. While electronic system 300 may be illustrated with a single processor, system 300 may include multiple processors and/or co-processors. In an embodiment, processor 310 includes an apparatus having heterostructures 100 in accordance with embodiments described herein. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment. In another embodiment, memory 320 includes an apparatus having heterostructures 100 as described herein.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a semiconductor substrate comprising silicon;
a buffer film epitaxially grown on the semiconductor substrate, the buffer film comprising silicon, germanium, and an impurity; and
a first semiconductor film epitaxially grown on the buffer film wherein a lattice mismatch exists between the semiconductor substrate and the first semiconductor film.

2. An apparatus according to claim 1 wherein the first semiconductor film comprises strained germanium and wherein the impurity provides stress relaxation between at least the semiconductor substrate and the first semiconductor film or wherein the impurity disrupts lattice structure dislocation gliding in at least the first semiconductor film.

3. An apparatus according to claim 1 wherein the first semiconductor film comprises compressively strained germanium and wherein the lattice mismatch is about 4%.

4. An apparatus according to claim 1 further comprising:
a second semiconductor film epitaxially grown on the first semiconductor film, the second semiconductor film comprising tensile-strained silicon wherein the first semiconductor film and second semiconductor film form a quantum well heterostructure for use as a channel material in a complementary metal-oxide-semiconductor (CMOS) device.

5. An apparatus according to claim 1 wherein the buffer film is selectively grown on active regions of the semiconductor substrate and wherein the impurity is a group IV isovalent of the semiconductor substrate.

6. An apparatus according to claim 1 wherein the impurity of the buffer film is carbon and wherein the buffer film comprises less than about 5% carbon by atomic percentage.

7. An apparatus according to claim 1 wherein the buffer film is about 10 to 50 nm thick and the ratio of silicon to germanium in the buffer film is about one atom of germanium for every atom of silicon.

8. A method comprising:
introducing an impurity to the surface of a substrate comprising silicon; and
epitaxially coupling a first semiconductor film with the substrate, the first semiconductor film comprising strained germanium wherein a lattice mismatch exists between the substrate and the first semiconductor film.

9. A method according to claim 8 wherein introducing an impurity comprises epitaxially depositing a buffer film comprising germanium and an impurity using atomic layer deposition (ALD), physical vapor deposition (PVD), chemical vapor deposition (CVD), or suitable combinations thereof, the buffer film being disposed between the substrate and the first semiconductor film, wherein the impurity disrupts lattice structure dislocation gliding in at least the first semiconductor film.

10. A method according to claim 9 wherein epitaxially depositing a buffer film comprises epitaxially depositing a buffer film comprising greater than or equal to about 50% germanium and less than about 5% carbon, wherein carbon is the impurity and the percentages are atomic percentages.

11. A method according to claim 9 wherein epitaxially depositing a buffer film comprises epitaxially depositing a buffer film comprising silicon, the buffer film having a thickness of about 10 to 50 nm wherein the atomic ratio of silicon to germanium in the buffer film is about one atom of germanium for every atom of silicon

12. A method according to claim 8 further comprising:
epitaxially depositing a second semiconductor film to the first semiconductor film, the second semiconductor film comprising strained silicon wherein the first semiconductor film and second semiconductor film form a quantum well heterostructure for use as a channel material in a complementary metal-oxide-semiconductor (CMOS) device.

13. A method according to claim 12 wherein the first semiconductor film comprises compressively strained germanium and the second semiconductor film comprises tensile-strained silicon.

14. A method according to claim 8 wherein introducing an impurity comprises selectively introducing an impurity to active regions of the semiconductor substrate and wherein the impurity is a group IV isovalent of the semiconductor substrate.

15. A method according to claim 8 wherein introducing an impurity comprises implanting a surface of the substrate with an impurity.
